(19) United States
(12) Patent Application Publication
(10) Pub. No.: US 2009/0126966 A1
(43) Pub. Date: May 21, 2009

(54) WIRE MANAGEMENT TRANSITION BLOCK

(75) Inventors: Robert Charles Flaig, Lancaster, PA (US); Kenneth Paul Dowhower, Harrisburg, PA (US); George Harold Douty, Mifflintown, PA (US); William Henry Bernhart, Elizabethtown, PA (US)

Correspondence Address: TYCO TECHNOLOGY RESOURCES, 4550 NEW LINDEN HILL ROAD, SUITE 140, WILMINGTON, DE, 19808-2952, US

(73) Assignee: TYCO ELECTRONICS CORPORATION, Middletown, PA (US)

(21) Appl. No.: 11/943,702

(22) Filed: Nov. 21, 2007

(51) Int. Cl. H05K 5/02

(52) U.S. Cl. 174/50

(57) ABSTRACT

A wire management transition system configured for placement in a floor panel of an aircraft system, and to be secured beneath a tracking strip. The system is configured to secure both data and power cables without damage to the wires. A top portion and bottom portion interconnect and are configured with grooves to secure both the data cables and power cables and prevent the cables from damage and external forces.

### FIELD OF THE INVENTION

The present invention is directed to a wire management system, and more specifically to a wire management system configured to route wire from beneath a floor surface to a seating system disposed above the floor surface.

### BACKGROUND OF THE INVENTION

In many systems, wires are required to provide electrical power or electronic control signals to components, such as computers, printers, auxiliary hardware, etc. . . . Often, these wires are required in areas with less than optimum conditions, e.g. areas with space constraints, harsh atmospheric conditions. In addition, these wires also require protection from shorts, damage, and other obstacles that may interfere with the transmission of the power or control signals. It is therefore desirable for a wire management system to provide support and protection to the wires transmitting the power or data.

In aircraft systems, each individual seat requires power or data for various purposes. Typically the power or data is routed to each seat via a seat track route or on top of the floor of the aircraft. The wires travel from the track route to each seat to provide the necessary power or data. The power and data that is transmitted through these wires must originate from one area, typically from beneath the area where the seats are located, and the wires must travel from the source through a space in the floor of the passenger area to the individual seats.

What is needed is a wire management system that can protect the wires in the floor. Specifically, a wire management system that has a low profile and protects the wires from damage.

### SUMMARY OF THE INVENTION

The present invention relates to a wire management system having a top portion with a first groove extending from openings in the top portion to receive wire and a bottom portion to cover the top portion and prevent the wire in the first groove from being exposed. The top portion and bottom portion are connected by a fastener and the wire management system is configured to fit into an aperture in a discrete location and route the wire.

The present invention further relates to a wire management system having an aircraft system, a top portion with a first groove extending from openings in the top portion to receive wire and a bottom portion to cover the top portion and prevent the wire in the first groove from being exposed. The top portion and bottom portion are connected by a fastener and the wire management system is configured to fit into an aperture in a floor panel of the aircraft system.

The present invention also relates to a wire management system having a top portion with a first groove extending from openings in the top portion to receive wire, a bottom portion to cover the top portion and prevent the wire in the first groove from being exposed and a chute extending from a side of the top portion to protect the wire from damage. The invention also includes a pivoting connection to connect the top portion and bottom portion. The top portion and bottom portion are connected by the pivoting connection and the wire management system fits into an aperture in a discrete location and route the wire.

An advantage of the present invention is that it provides support for the seat track cover in the area where the wires are routed through the floor, which permits the track cover to hold the maximum required downward, side and abuse loads.

Another advantage of the present invention is that it provides protection for the wires being routed from beneath the floor to the seating system.

Other features and advantages of the present invention will be apparent from the following more detailed description of the preferred embodiment, taken in conjunction with the accompanying drawings which illustrate, by way of example, the principles of the invention.

### BRIEF DESCRIPTION OF THE DRAWINGS

FIG. 1 illustrates an exploded view of the wire management transition block of the present invention.

FIG. 2 illustrates a perspective view of the assembled transition block of the present invention.

FIG. 3 illustrates a perspective view from the top of the transition block.

FIG. 4 illustrates a bottom perspective view with the hinge mechanism.

FIG. 5 illustrates an exploded view of the hinge mechanism.

FIG. 6 illustrates a perspective view of an assembled transition block.

FIG. 7 illustrates a partial perspective view of the transition block.

FIG. 8 illustrates an enlarged partial perspective view of the transition block.

FIG. 9 illustrates an exploded view of an alternate embodiment.

Wherever possible, the same reference numbers will be used throughout the drawings to refer to the same or like parts.

### DETAILED DESCRIPTION OF THE INVENTION

The present invention is directed to a wire management system that manages wire routing between the floor and the seat track cover in a transportation vessel, e.g. an aircraft. It is to be appreciated that while an aircraft application is referred to throughout this detailed description, the wire management system of the present invention can be used with any vessel or apparatus using wires that can benefit from disposing wires, flexible tubing, hydraulics and pneumatic conduits in a wire management system between two separate defined areas, such as a floor and seat track.

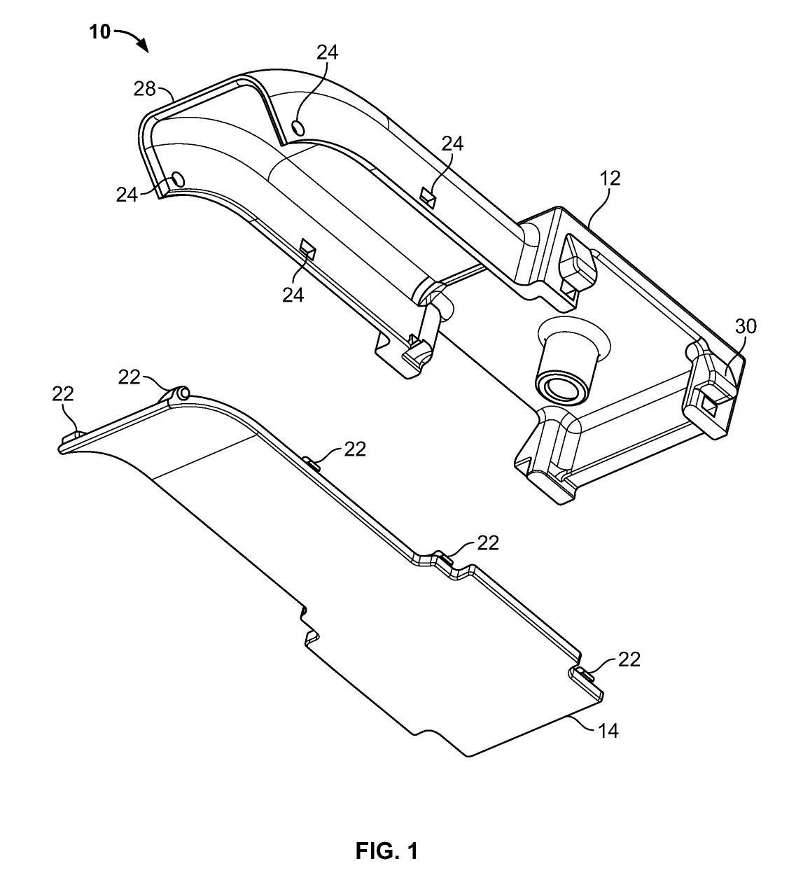

FIG. 1 shows an opened view of the wire management transition housing 10 having a housing portion 12 and a cover portion 14. The transition housing 10 is also configured with latches 22 positioned on the sides of the cover portion 14 to fasten the housing portion 12 to the cover portion 14. The housing portion 12 has corresponding latch receptacles 24 that engage with the latches 22 of the cover portion 14 when the cover portion 14 is placed in the housing portion. Additional latches 30 on the sides of the housing portion secure the transition housing 10 in the seat track of the aircraft. The housing portion 12 of the transition block 10 has a chute portion 28 protruding from the front side that protects the wires entering the transition block 10.

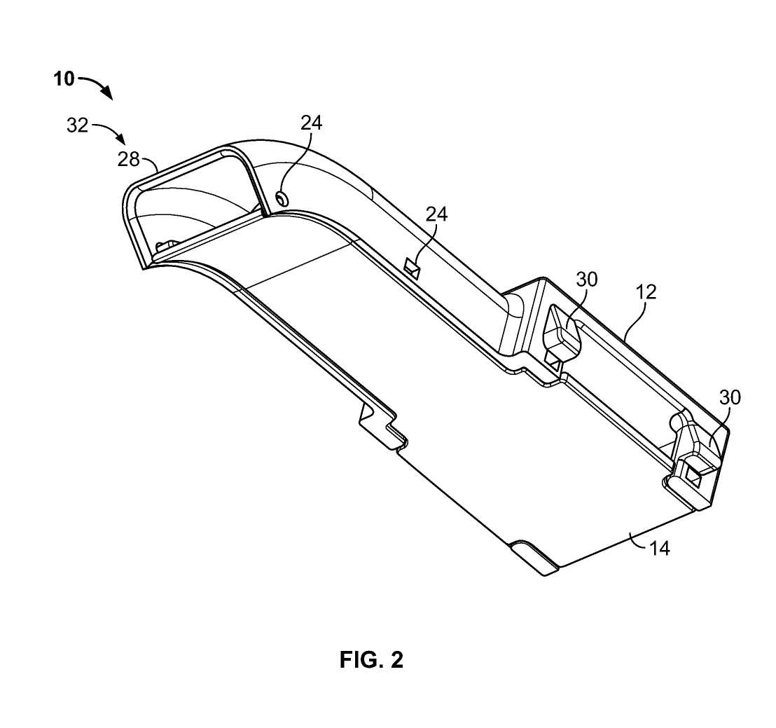

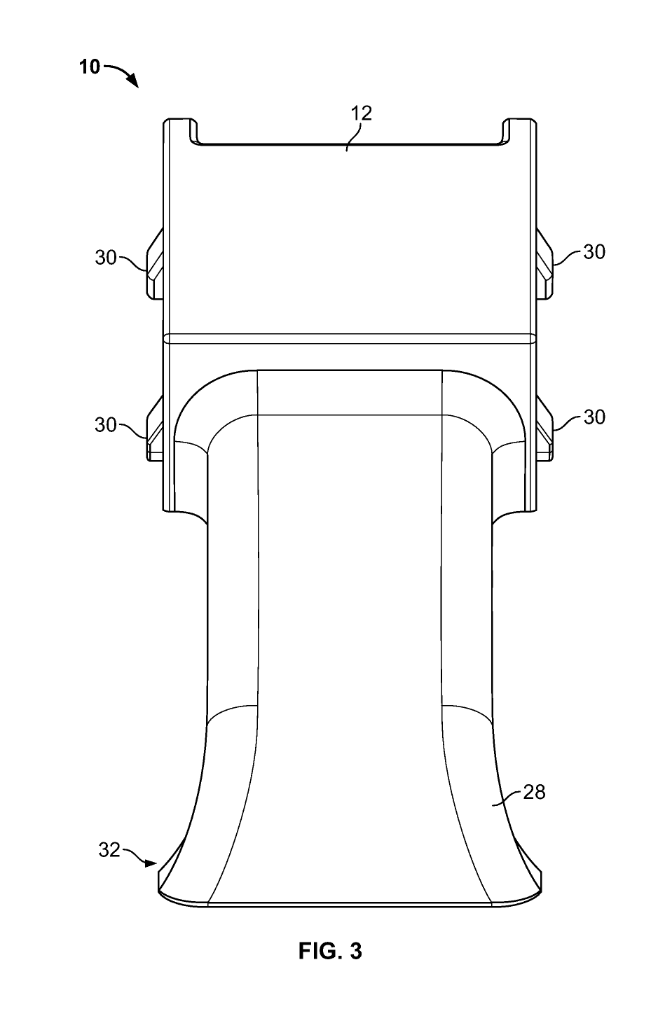

FIG. 2 illustrates the transition housing 10 in the closed position with the cover portion secured to the housing portion. The closed position occurs when the cover portion 14 is placed into the housing portion 12 and the latches 22 are engaged with the latch receptacles 24. The chute portion 28 protruding from the front side protects the wires from being bent, abrased, or crushed by forces that that may damage the wires. FIG. 3 shows a top view of the chute portion 28, illustrating the fluted end 32, which provides additional protection for the wires. The fluted end 32 allows the wires to be routed and bend or flex without contacting a sharp edge that may rub, bend, crush and ultimately damage the wire. FIG. 3 also illustrates the latches 30 that protrude from the sides of the housing portion 12 that secure the wire management system to the seat track when in place.

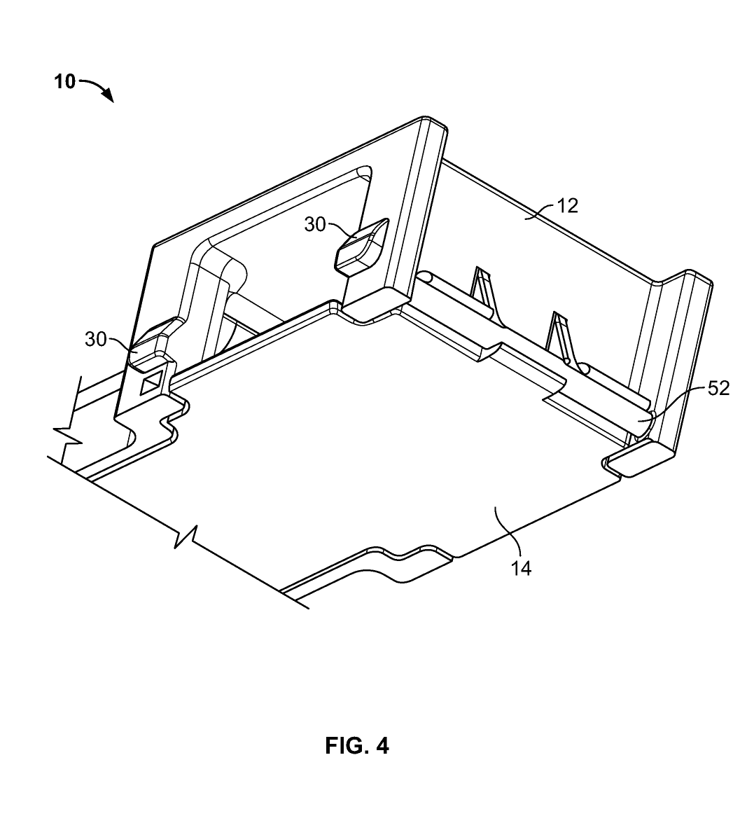

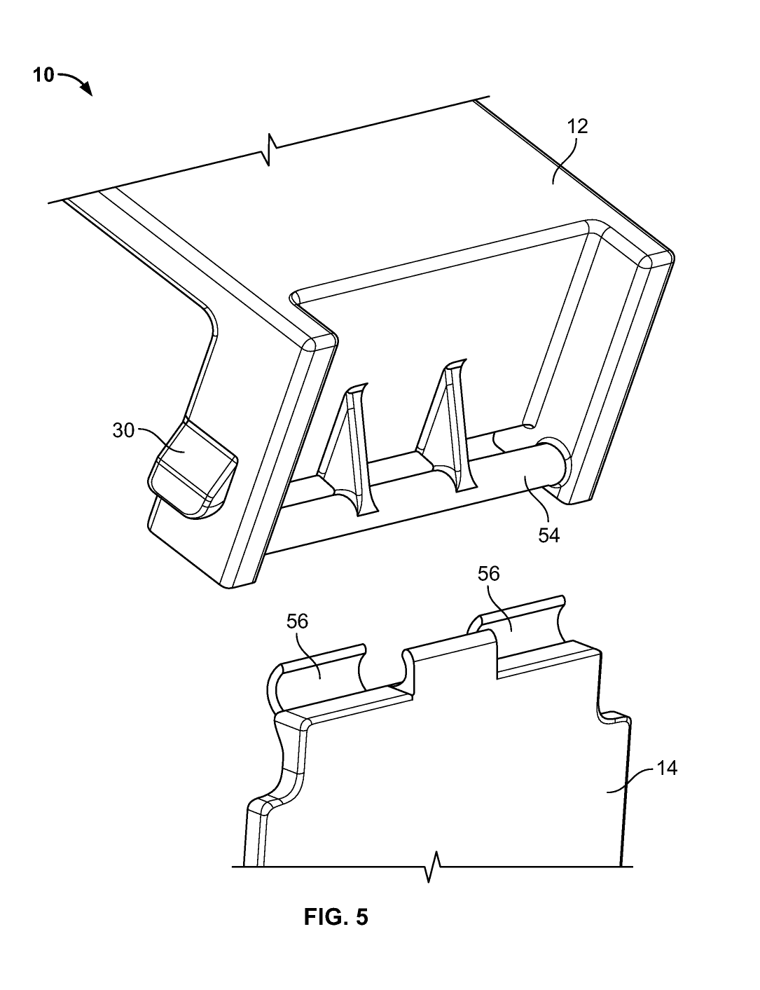

FIGS. 4 and 5 illustrate the cover portion 14 attached to the housing portion 12 with a hinge 52. The hinge 52 is separable, with the hinge posts 54 located on one portion of the housing 10 and the hinge fingers 56 located on the opposite portion of the housing 10 (FIG. 5). FIG. 5 shows the hinge fingers 56 disposed on the cover portion 14 and the hinge posts 54 disposed on the housing portion 12, however, the hinge fingers 56 may be disposed on the housing portion 12 and the hinge posts 54 may be disposed on the cover portion 14. The hinge fingers 56 attach to the hinge posts 54 and create a secure, rotatable connection, allowing the housing portion 12 and the cover portion 14 to be connected and open without separation (shown in FIG. 4). The hinge 52 acts in conjunction with the latches 22 to fasten the housing portion 12 to the cover portion 14.

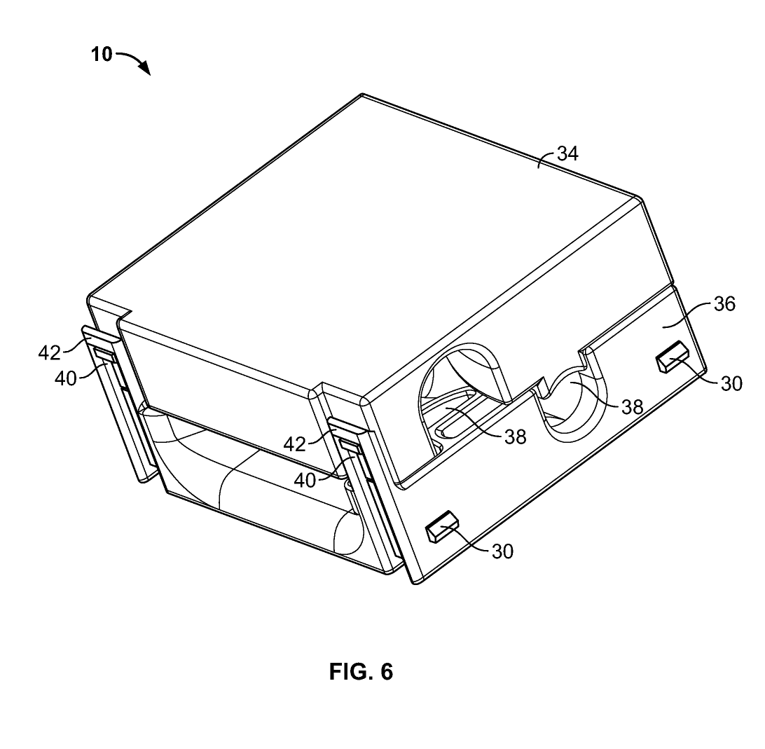

FIGS. 6-8 illustrates another embodiment of the wire management transition housing 10 having a top portion 34 and a bottom portion 36. FIG. 6 illustrates a closed view of the housing 10. Both portions 34, 36 have grooves 38. The groove 38 is shaped such that a cable or wire could lay in the groove 38 without being pinched, crushed, or otherwise obstructed or damaged by the other portion 34, 36 of the housing 10. The wires enter and/or exit the housing 10 through the groove 38 openings on the side of the housing 10.

The housing 10 is also configured with latches 40 on the bottom portion 36 of the housing 10. The top portion 34 has a pair of corresponding latch receptacles 42 that engage with the latches 40 of the bottom portion 36 when the top portion 34 is in the closed position. While it has been described that the latches 40 are located on the bottom portion 36 of the housing 10 and the latch receptacles 42 are located on the top portion 34 of the housing 10, it will be known by those skilled in the art that the latches 43 may be located on the top portion 34 of the housing 10 and the latch receptacles 42 may be located on the bottom portion 36 of the housing 10.

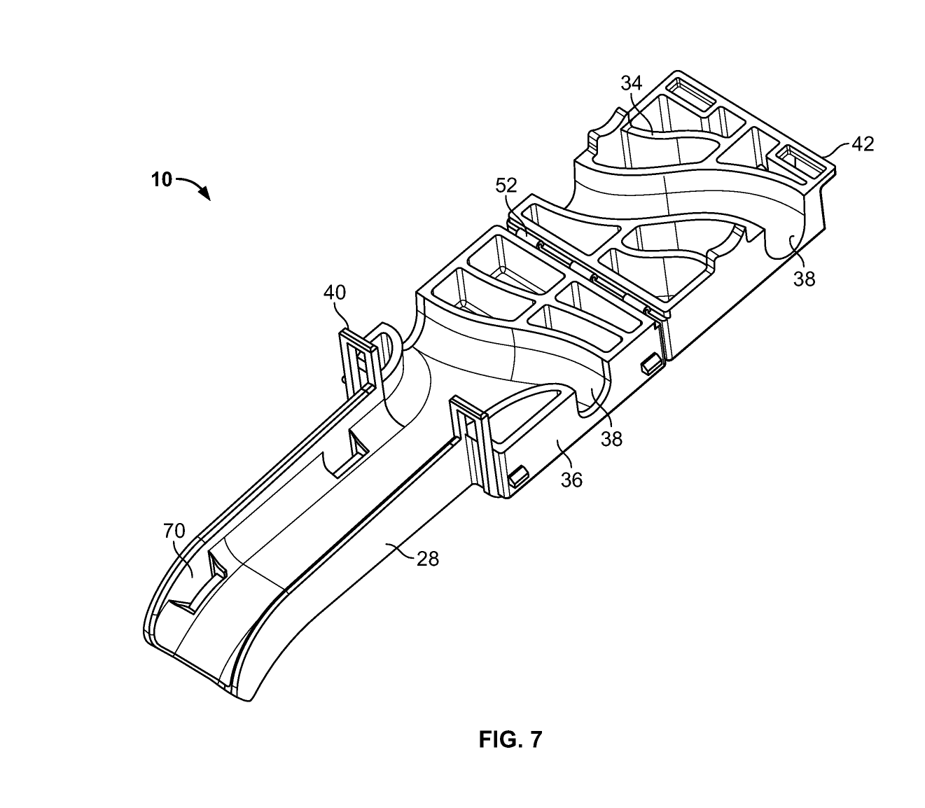

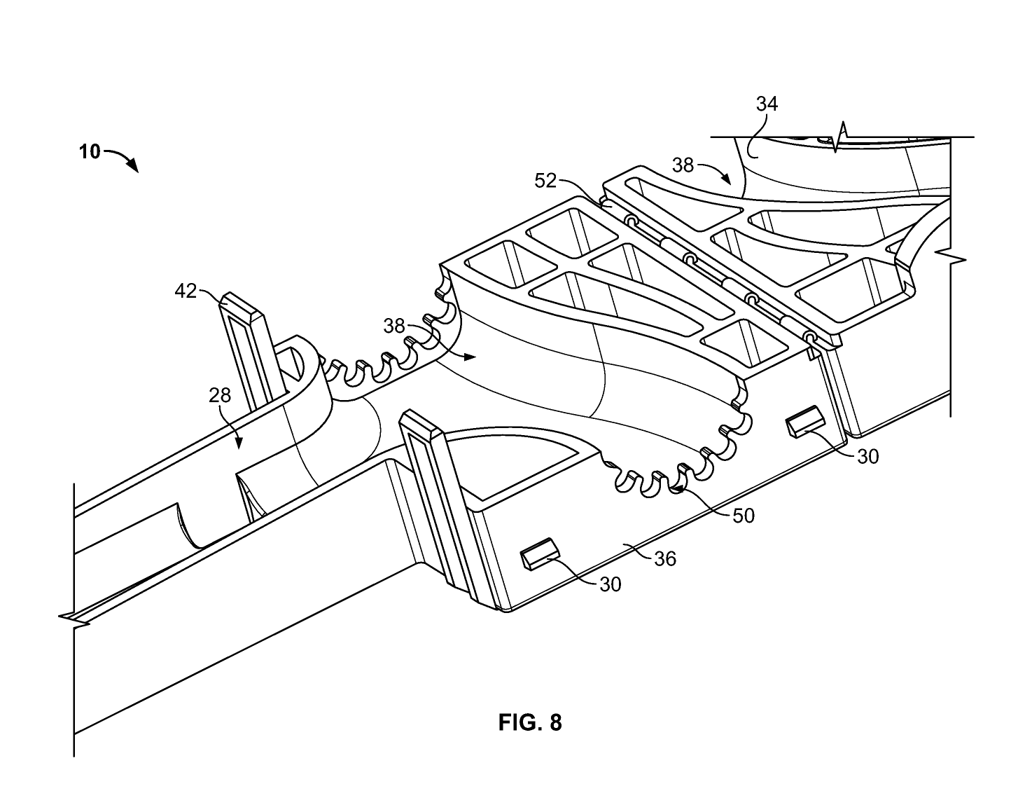

FIG. 7 illustrates the housing 10 in an open position. A hinge 48 may be used to connect the top portion 34 and the bottom portion 36. Further, FIG. 7 illustrates an alternative latch 40 and latch receptacle 42 arrangement that can be used for the present invention. The chute 28 may also have receptacles 70 that accommodate the use of wire ties or other fastener to secure the wires (not shown) in the chute. In addition, as shown in FIG. 8, a wire rake 50 may be used to facilitate routing individual wire through the groove 38. The housing may also include latches 30 disposed on the side of the housing 10 to secure the housing 10 to the seat track, or any other surface used in conjunction with the housing 10. FIG. 8 also illustrates an alternate embodiment of the present invention having a chute portion 28 that protects the wires entering the housing 10.

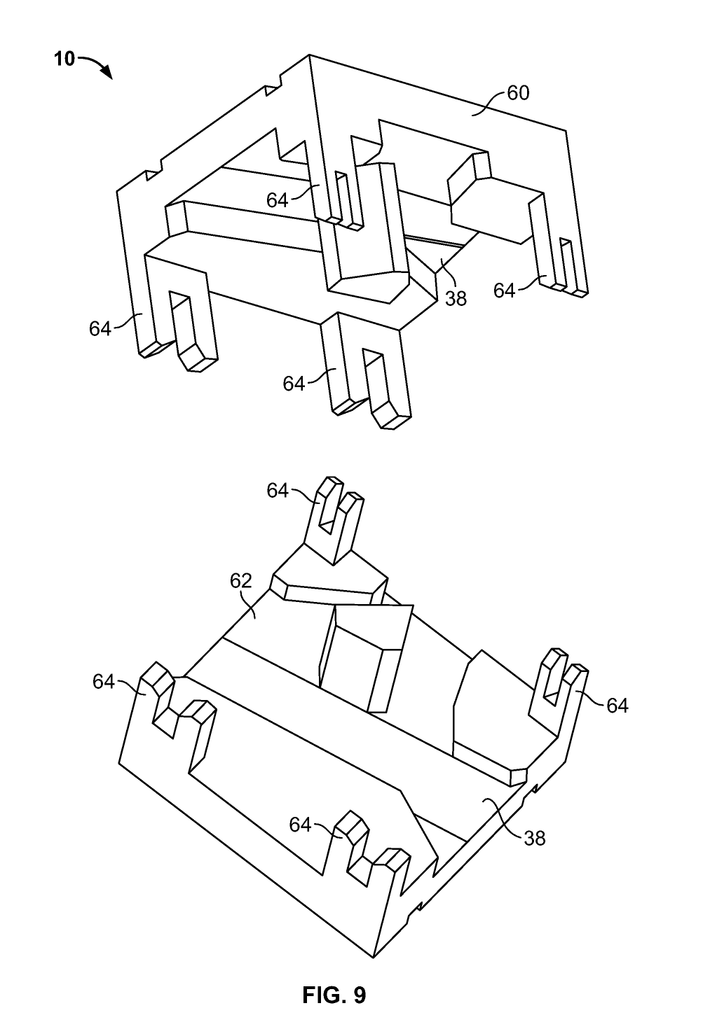

FIG. 9 illustrates another embodiment of the present invention where a top portion 60 and a bottom portion 62 are connected with fasteners 64. The fasteners 64 replace or supplement the hinges shown in FIGS. 6-8. FIG. 9 illustrates the use of four fasteners 64, however, it is understood that more or less fasteners may be used. Both the top 60 and bottom 62 portions have grooves 66 for the wires to be placed. When connected, the fasteners 64 on both the top 60 and bottom 62 portions link to secure the top 60 and bottom 62 portions together.

While the invention has been described with reference to a preferred embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A wire management system comprising:
a top portion configures to receive a plurality of wires having a first groove extending between a pair of openings in the top portion;
a bottom portion configured to prevent the plurality of wires in the first groove from being exposed; and
wherein the top portion covers the bottom portion and the top portion and bottom portion are connected by a fastener and wherein the wire management system is configured to fit into an aperture in a predetermined location.

2. The wire management system of claim 1, further comprising a chute extending from a side of the top portion, configured to protect the wire from damage.

3. The wire management system of claim 1 wherein the fastener is a hinge mechanism.

4. The wire management system of claim 1 wherein the top portion and bottom portion are connected by a least one fastener.

5. The wire management system of claim 4 wherein the plurality of fasteners includes latches.

6. The wire management system of claim 5 wherein the plurality of fasteners includes a hinge mechanism.

7. The wire management system of claim 1 wherein the pair of openings in the top portion further comprise wire rakes configured to route the plurality of wires.

8. The wire management system of claim 1 wherein the bottom portion further comprises a second groove extending between a pair of openings in the bottom portion, and configured to receive a second wire.

9. A wire management system for routing wires in an aircraft comprising:
an aircraft having a floor panel;
a top portion configures to receive a plurality of wires having a first groove extending between a pair of openings in the top portion;
a bottom portion configured to prevent the plurality of wires in the first groove from being exposed; and
wherein the top portion covers the bottom portion and the top portion and bottom portion are connected by a fastener and wherein the wire management system is configured to fit into an aperture in the floor panel of the aircraft system.

10. The wire management system of claim 9, further comprising a chute extending from a side of the top portion, configured to protect the wire from damage.

11. The wire management system of claim 9 wherein the fastener is a hinge mechanism.

12. The wire management system of claim 9 wherein the top portion and bottom portion are connected by a least one fastener.

13. The wire management system of claim 12 wherein the plurality of fasteners includes latches.

14. The wire management system of claim 13 wherein the plurality of fasteners includes a hinge mechanism.

15. The wire management system of claim 9 wherein the pair of openings in the top portion further comprise wire rakes configured to route the plurality of wires.

16. The wire management system of claim 9 wherein the bottom portion further comprises a second groove extending between a pair of openings in the bottom portion, and configured to receive a second wire.

17. A wire management system comprising:
a top portion configures to receive a plurality of wires having a first groove extending between a pair of openings in the top portion;
a bottom portion configured to prevent the plurality of wires in the first groove from being exposed;
a chute extending from a side of the top portion, configured to protect the plurality of wires from damage;
a pivoting connection configured to connect the top portion and bottom portion; and
wherein the wire management system is configured to fit into an aperture in a predetermined location.

18. The wire management system of claim 17 wherein the openings in the top portion further comprise wire rakes configured to route the wire.

19. The wire management system of claim 17 wherein the bottom portion further comprises a second groove extending from a plurality of openings in the bottom portion, and configured to receive a plurality of wires.
